(19) United States
(12) Patent Application Publication
(10) Pub. No.: US 2019/0006593 A1
(43) Pub. Date: Jan. 3, 2019

(54) METHOD FOR STRETCHING SUB MASK, MASK, AND PANEL

(71) Applicants: BOE TECHNOLOGY GROUP CO., LTD., Beijing (CN); CHENGDU BOE OPTOELECTRONICS TECHNOLOGY CO., LTD., Chengdu (CN)

(72) Inventors: Jianpeng WU, Beijing (CN); Lan LAN, Beijing (CN); Zhongying YANG, Beijing (CN); Yinan LIANG, Beijing (CN); Fengli JI, Beijing (CN)

(21) Appl. No.: 15/736,010

(22) PCT Filed: Jun. 8, 2017
(86) PCT No.: PCT/CN17/87619

§ 371 Date: Dec. 13, 2017

(30) Foreign Application Priority Data
Jul. 25, 2016 (CN) 201610590318.9

(51) Int. Cl. H01L 51/00; C23C 14/04; C23C 14/24; H01L 51/56

(52) U.S. Cl. CPC H01L 51/0011; C23C 14/042; H01L 51/56; H01L 51/001; C23C 14/24

(57) ABSTRACT

The present disclosure relates to the field of display technology, in particular, to a method for stretching a sub mask, a mask, and a panel. In the present disclosure, the stretcher holds the holding regions positioned at four corners of the sub mask to be stretched, and stretches the sub mask with a first tension along a direction having a first angle with respect to an extending direction of a long side of the sub mask in a plane where the sub mask is located.

### CROSS REFERENCE

The present application is based upon International Application No. PCT/CN2017/087619, filed on Jun. 8, 2017, which is based upon and claims priority to Chinese Patent Application No. 201610590318.9, filed on Jul. 25, 2016, and the entire contents thereof are incorporated herein by reference.

### TECHNICAL FIELD

The present disclosure relates to the field of display technology, in particular, to a method for stretching a sub mask, a mask, and a panel.

### BACKGROUND

Nowadays, in the vapor deposition process, an ultra-fine mask is often used to deposit organic light-emitting material on a predetermined position on the substrate. The flatness of the ultra-fine mask directly affects the effect of the vapor deposition. A finer ultra-fine mask is required as the resolution of the panel becomes higher, which in turn has a higher requirement on the flatness of the ultra-fine mask.

It should be noted that, information disclosed in the above background portion is provided only for better understanding of the background of the present disclosure, and thus it may contain information that does not form the prior art known by those ordinary skilled in the art.

### SUMMARY

Embodiments of the present disclosure provide a method for stretching a sub mask, a mask, and a panel.

Embodiments of the present disclosure adopt the technical solutions that follow.

A method for stretching a sub mask includes:

holding holding regions positioned at four corners of the sub mask to be stretched;

stretching the sub mask with a first tension along a direction having a first angle with respect to an extending direction of a long side of the sub mask in a plane where the sub mask is located;

fixing the sub mask when a flatness of the sub mask reaches a first reference value.

Optionally, the first tension is substantially symmetrical with respect to a center of the sub mask.

Optionally, at least two tensions among the first tension are substantially symmetrical respect to an axis passing through a center of the sub mask.

Optionally, a component force of the first tension in an extending direction of a short side of the sub mask reduces as a size ratio of the sub mask decreases,

wherein the size ratio of the sub mask is a ratio between the short side and the long side of the sub mask.

Optionally, a component force of the first tension in an extending direction of a short side of the sub mask is substantially constant during the stretching.

Optionally, the stretching the sub mask with a first tension along a direction having a first angle with respect to an extending direction of a long side of the sub mask in a plane where the sub mask is located further includes:

stretching the sub mask with a varying first tension along a direction having a varying first angle with respect to the extending direction of the long side of the sub mask; or

stretching the sub mask with a fixed first tension along a direction having a fixed first angle with respect to the extending direction of the long side of the sub mask.

Optionally, a component force of the first tension in an extending direction of a short side of the sub mask is gradually reduced during the stretching.

Optionally, the stretching the sub mask with a first tension along a direction having a first angle with respect to an extending direction of a long side of the sub mask in a plane where the sub mask is located further includes:

stretching the sub mask with a fixed first tension along a direction having a gradually reduced first angle with respect to the extending direction of the long side of the sub mask; or

stretching the sub mask with a gradually reduced first tension along a direction having a fixed first angle with respect to the extending direction of the long side of the sub mask.

Optionally, the first angle is greater than 0 degree and smaller than 90 degrees.

A mask including a mask frame and a plurality of sub masks fixed to the mask frame, wherein the sub masks are stretched using the above method.

Optionally, the sub mask is formed of metal.

A substrate is formed using the above mask.

A display device includes the above substrate.

A stretcher includes:

a holder, configured to hold holding regions positioned at four corners of a sub mask to be stretched; and

a rotation shaft, connected to the holder, the rotation shaft being able to change a direction to stretch the sub mask with a first tension along a direction having a first angle with respect to an extending direction of a long side of the sub mask in a plane where the sub mask is located.

It is to be understood that both the foregoing general description and the following detailed description are exemplary and explanatory only and are not restrictive of the disclosure, as claimed.

This section provides a summary of various implementations or examples of the technology described in the disclosure, and is not a comprehensive disclosure of the full scope or all features of the disclosed technology.

### BRIEF DESCRIPTION OF THE DRAWINGS

In order to more clearly illustrate the technical solutions of the embodiments of the present disclosure, drawings of the embodiments of the present disclosure will be briefly described below. It will be apparent that the drawings in the following description refer only to some embodiments of the present disclosure, and other drawings are available to those of ordinal skill in the art based on these drawings without creative work.

FIG. 1 illustrates a schematic diagram of a structure of an ultra-fine mask;

FIG. 2 illustrates a schematic diagram of a principle of stretching a sub mask using the method for stretching the sub mask;

FIG. 3 is a flow chart illustrating a method for stretching the sub mask according to embodiments of the present disclosure;

FIGS. 4a to 4b illustrate schematic diagrams of principles of stretching a sub mask using the method for stretching the sub mask according to embodiments of the present disclosure; and

FIG. 5 is a schematic diagram illustrating a stress analysis of any holding region according to embodiments of the present disclosure.

### DETAILED DESCRIPTION

In order to make the objectives, technical solutions and advantages of the embodiments of the present disclosure more clear, the embodiments of the present disclosure will be described in further detail in conjunction with the accompanying drawings. It is obvious that the described embodiments are part of the embodiments rather than all embodiments of the present disclosure. All other embodiments obtained by one of ordinary skill in the art based on the described embodiments of the present disclosure without the need for creative work are within the protection scope of the present disclosure.

Hereinafter, technical solutions of implementations of the present disclosure will be described in detail with reference to particular embodiments, and the present disclosure includes but is not limited to these embodiments.

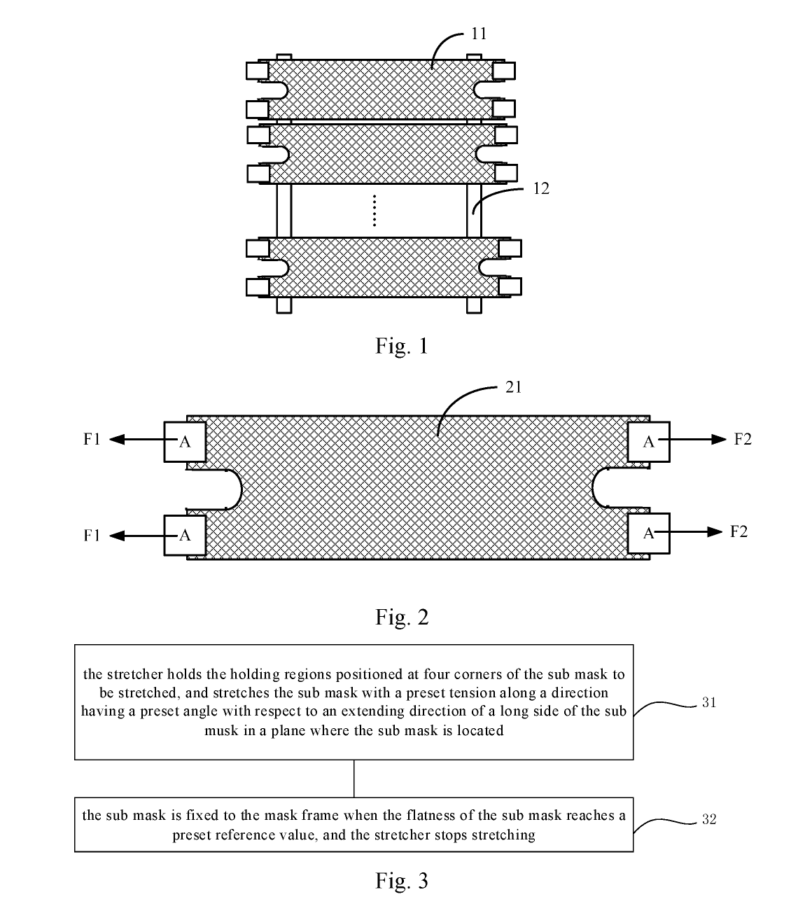

FIG. 1 illustrates a schematic diagram of a structure of an ultra-fine mask. As illustrated in FIG. 1, the ultra-fine mask is formed by splicing a plurality of sub masks 11 and fixing the sub masks 11 to a mask frame 12 respectively. However, if a relatively high flatness of each sub mask is required, each sub mask is required to be stretched using a stretching method. In particular, in a method for stretching a sub mask, the stretcher holds four stretching regions of the sub mask, stretches the sub mask with a horizontal tension, and welds the sub mask to the mask frame by laser. FIG. 2 illustrates a schematic diagram of a principle of stretching a sub mask using the method for stretching the sub mask. As illustrated in FIG. 2, the stretcher makes contact with the holding regions A positioned at four corners of the sub mask 21, which are tension bearing regions of the sub mask 21. As can be seen from the stress analysis of the sub mask 21, the sub mask 21 is mainly subjected to a horizontal tension F1 and an opposite horizontal tension F2 of the stretcher at this time. The tension spreads in the sub mask 21 by the transmission of the medium material, such that the sub mask 21 is tensioned. As can be seen from FIG. 2, both sides of the long side of the sub mask is subjected to a relatively greater force and thus have a relatively larger deformation, and the middle part is subjected to a relatively smaller force and thus has a relatively smaller deformation. The extending direction of the short side may be changed due to the force along the extending direction of the long side, or even a wrinkle across the sub mask may occur, which may seriously affect the flatness of the sub mask, thereby affecting the subsequent vapor deposition process and reducing product yield.

As illustrated in FIG. 3, which is a flow chart illustrating a method for stretching the sub mask according to embodiments of the present disclosure, the method for stretching the sub mask mainly includes the following steps.

The stretcher holds the holding regions positioned at four corners of the sub mask to be stretched, and stretches the sub mask with a first tension along a direction having a first angle with respect to an extending direction of a long side of the sub mask in a plane where the sub mask is located.

The sub mask is fixed to the mask frame when the flatness of the sub mask reaches a first reference value, and the stretcher stops stretching.

In the present embodiment, the first reference value of the flatness may be set based on experience. With respect to the flatness of the sub mask, it is possible to be monitored in real time. Namely, during the applying of the force, the flatness of the surface of the sub mask caused by the applying of the force is obtained in real time using a sensor, and whether the flatness has reaches the first reference value is analyzed. If positive, it means that the flatness of the sub mask is saturated, and sinking and wrinkles are minimized. Accordingly, the sub mask may be welded and fixed to the mask frame by laser. Afterwards, the holding regions may be cut off and trimmed according to general manner. If negative, further force may be applied until the flatness reaches the first reference value.

It should be noted that the stretcher according to the present embodiment may be a general stretcher, and the holder of the stretcher that is configured to hold the four holding region of the sub mask may be controlled using a rotation shaft whose direction is variable, such that the direction of the first tension is variable.

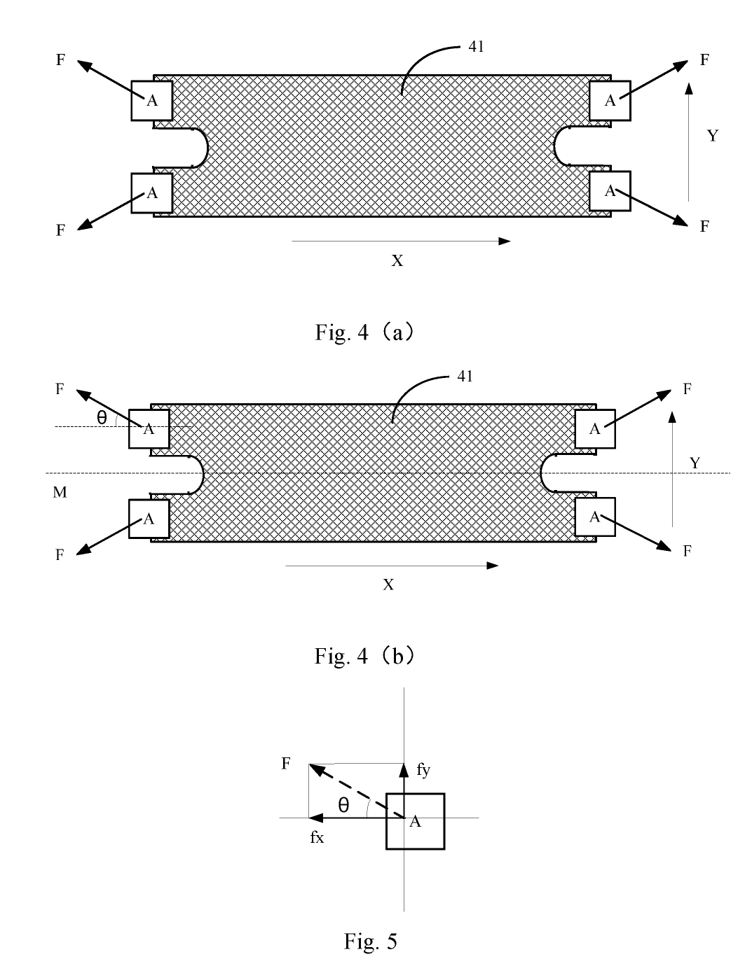

Referring to FIG. 4a, the stretcher holds the holding regions A positioned at four corners of the sub mask 41 to be stretched, and stretches the sub mask 41 with a first tension F along a direction having a first angle θ with respect to an extending direction (i.e., the X direction) of a long side of the sub mask 41 in a plane where the sub mask 41 is located. Accordingly, a component force may be applied along an extending direction (i.e., the Y direction) of the short side of the sub mask 41, such that the sub mask 41 is stretched along the extending direction of the short side of the sub mask 41 in addition to being stretched along the extending direction of the long side of the sub mask 41. Accordingly, the wrinkles of the sub mask 41 may be reduced and the flatness of the sub mask may be improved.

In the above stretching method, the force applied in each holding region may be different, however, in order to improve the flatness after the stretching, the step 31 is optionally performed as follows: in particular, the sub mask is stretched with a first tension along a direction having a first angle with respect to an extending direction of a long side of the sub mask in a plane where the sub mask is located in a substantially centrosymmetric manner. In the present embodiment, stretching in a substantially centrosymmetric manner involves the case where the first tension applied to each holding region is identical, and the first angle is also identical. In actual practices, considering the type of the fine mask, the thickness thereof is relative slimmer, and during the stretching, it is possible to ensure better stretching by stretching substantially symmetrically, and therefore avoiding such problems as fracture due to uneven stretching.

Further, step 31 may also be performed as follows: with respect to at least two holding regions, the sub mask is stretched with a first tension along a direction having a first angle with respect to an extending direction of a long side of the sub mask in a plane where the sub mask is located in a substantially axisymmetric manner. For example, referring to FIG. 4b, only the two holding regions at the left side of the sub mask are stretched along the directions having the first angle, and the directions are substantially symmetric with respect to the axis M passing through a center of the sub mask; and the two holding regions at the right side of the sub mask are stretched according to the previous embodiment. Alternatively, only the two holding regions at the upper side of the sub mask are stretched along the directions having the first angle, and the directions are substantially symmetric with respect to the axis (i.e., the axis along the Y direction) passing through a center of the sub mask; and the two holding regions at the lower side of the sub mask are stretched according to the previous embodiment. Considering the slimness of the sub mask, the first tension can be set reasonably to prevent the sub mask from breaking during the stretching. In the present disclosure, the term substantially symmetric may include the case where the directions are deemed to be symmetric with an acceptable tolerance, e.g., 10%, 5%, 3%, 2%, 1% or the like, while the present disclosure is not limited to the above specific percentages.

Further, the sub mask may have different sizes according to different sizes of the fine mask. Optionally, a component force of the first tension in an extending direction of a short side of the sub mask reduces as a size ratio of the sub mask decreases. In the present disclosure, the size ratio of the sub mask is a ratio between the short side and the long side of the sub mask. For example, with respect to a sub mask having a ratio of 1/5 between the short side and the long side, the component force in an extending direction of a short side of the sub mask of the suitable first tension applied to the holding region is f1; while with respect to the sub mask having a ratio of 1/6 between the short side and the long side, the component force in an extending direction of a short side of the sub mask of the suitable first tension applied to the holding region is f1×4/5. Alternatively, with respect to a sub mask having a ratio of 1/5 between the short side and the long side, the component force in an extending direction of a short side of the sub mask of the suitable first tension applied to the holding region is f1; while with respect to the sub mask having a ratio of 1/6 between the short side and the long side, the component force in an extending direction of a short side of the sub mask of the suitable first tension applied to the holding region is f1×5/6. The numerals are provided herein for illustrating only, and the actual proportion thereof may be determined according to the actual size and material of the sub mask.

In the embodiments of the present disclosure, as can be seen from the above implementations, the wrinkles generated during the stretching of the sub mask may be improved as long as a component force of the first tension is applied to the holding regions along the extending direction of the short side of the sub mask. Optionally, all of the first tension applied to the four holding regions may have the component force along the extending direction of the short side of the sub mask. Accordingly, the effect of improvement may be more effectively improved. In particular, there may be flexible implementations such as: the stretcher stretches the sub mask with a fixed first tension along a direction having a varying first angle with respect to the extending direction of the long side of the sub mask, or the stretcher stretches the sub mask with a varying first tension along a direction having a fixed first angle with respect to the extending direction of the long side of the sub mask, or the stretcher stretches the sub mask with a varying first tension along a direction having a varying first angle with respect to the extending direction of the long side of the sub mask, or the stretcher stretches the sub mask with a fixed first tension along a direction having a fixed first angle with respect to the extending direction of the long side of the sub mask. In the present embodiment, the “fixed” or “varying” of the first tension indicates the magnitude of the first tension. Also, the first tension of the stretcher may have a preset initial value, and the varying first tension may increase or decrease from said initial value. Similarly, the first angle may have a preset initial value.

In an optional implementation, regardless of being stretching substantially symmetrically or asymmetrically, the component force of the first tension in the extending direction of the short side of the sub mask is substantially constant during the stretching, thus ensuring the stationarity of the stretching. In the present disclosure, the term “substantially constant” may refer to the case where the fluctuation of the force (or other parameters such as directions or the like) is very small, e.g., smaller than 10%, 5%, 3%, 2%, 1% or the like, while the present disclosure is not limited to the above specific percentages.

In particular, the following two approaches are possible to ensure that the component force of the first tension in the extending direction of the short side of the sub mask is substantially constant.

Approach I: the stretcher stretches the sub mask with a varying first tension along a direction having a varying first angle with respect to the extending direction of the long side of the sub mask.

In particular, referring to FIG. 5, which is a schematic diagram illustrating a stress analysis of any holding region, the stretcher controls the magnitude of the applied first tension F, which may gradually increase, gradually decrease or vary irregularly. Correspondingly, the first angle θ between the first tension F and the extending direction of the long side of the sub mask may cooperate with the first tension F, such that the component force fy of the first tension F along the extending direction of the short side of the sub mask is substantially constant. In actual practice, there may be the following equations:

the component force of the first tension F along the extending direction of the short side of the sub mask: fy=F×sin θ; and

the component force of the first tension F along the extending direction of the long side of the sub mask: fx=F×cos θ.

In the present disclosure, the component force fx gets little attention, and the magnitude may be substantially constant or variable, which will have little effect on decreasing the wrinkles occurred along the extending direction of the short side. Accordingly, with respect to fy=F×sin θ, if the fy is required to be substantially constant, the F is inversely proportional to sin θ. In the first approach (i.e., approach I), since both the first tension and the first angle are variable, and taking into account the inverse proportional relationship therebetween, F correspondingly varies with respect to sin θ. For example, if the first tension F varies to F/2, the sine value of the first angle varies to 2 sin θ. In addition, sine the first tension and the first angle may have a randomly defined initial value, it should be noted that a reference parameter is required in this case. For example, the first tension may be firstly set to an initial value, and then the initial value of the first angle may be determined according to the initial value of the first tension.

According to the first approach, a plurality of schemes of applying tension for stretching are possible, and thus more flexible stretching may be realized. Meanwhile, the wrinkles of the sub mask after stretching may be reduced, thereby improving flatness of the sub mask.

Approach II: the stretcher stretches the sub mask with a fixed first tension along a direction having a fixed first angle with respect to the extending direction of the long side of the sub mask.

As illustrated in FIG. 5, with respect to fy=F×sin θ, if the fy is required to be substantially constant, the F is inversely proportional to sin θ. In the second approach (i.e., the approach II), since the first tension and the first angle are fixed, and taking into account the inverse proportional relationship therebetween, F and sin θ are correspondingly determined with respect to each other. For example, if the first tension F is determined as F/2, the sine value of the first angle is determined as 2 sin θ, and the magnitude and direction of the first tension is substantially constant during the entire stretching process. However, with respect to different sub masks, the applied first tension when stretching may be different, while the first tension and the first angle are substantially constant as long as the stretching operation of the stretching process starts.

The stretching method according to the second approach is relatively simpler, and thus it may facilitate the mass production of the stretching of the sub mask. Meanwhile, the wrinkles of the sub mask after stretching may be reduced, thereby improving flatness of the sub mask.

According to another optional implementation, during the stretching, the component force of the first tension in the extending direction of the short side of the sub mask is gradually reduced. In actual practice, taking into account that the stretching process is a process gradually approaching the finish point, the first tension required by the stretching may be gradually reduced during the stretching to meet the stretching condition. Further, as the sub mask gradually becomes thinner, the component force of the first tension in the extending direction of the short side of the sub mask required in the latter stretching may be gradually reduced with the increase of the flatness. Accordingly, it is possible to avoid breaking of the sub mask due to over-stretching.

In particular, referring back to the equation fy=F×sin θ, the following two approaches are possible to ensure that the component force of the first tension in the extending direction of the short side of the sub mask is gradually reduced.

Approach III: the stretcher stretches the sub mask with a fixed first tension along a direction having a gradually reduced first angle with respect to the extending direction of the long side of the sub mask.

As illustrated in FIG. 5, the magnitude of first tension applied by the stretcher is substantially constant, for example, the first tension has a magnitude of F, and the initially applied first angle may be randomly set within a value range. For example, the initial first angle θ may be set as 60 degrees. The first angel gradually decreases with the same step length or different step lengths. Accordingly, it may facilitate determining the relation between the first angle and the sub mask, thereby simplifying operation and the equipment structure, and reducing the cost for sub mask stretching. In addition, in the approach, the stretching along the extending direction of the short side of the sub mask uniformly decreases to zero, thereby avoiding breaking of the sub mask.

Approach IV: the stretcher stretches the sub mask with a gradually reduced first tension along a direction having a fixed first angle with respect to the extending direction of the long side of the sub mask.

As illustrated in FIG. 5, the magnitude of first tension applied by the stretcher decreases with the same step length or different step lengths, and the first angle is substantially constant. For example, the first angle may be empirically or randomly set as a fixed angle θ, and the first tension reduces from F. According to the present approach, the stretching along both the extending directions of the long side and the short side of the sub mask uniformly decreases to zero, thereby avoiding breaking of the sub mask due to the continuous stretching when the sub mask has been already fully stretched.

Optionally, taking into account that a component force is required along the extending direction of the short side of the sub mask, the first angle may be greater than 0 degree and smaller than 90 degrees. It should be noted that the first angle indicates the acute angle between the edges without considering the two extending directions of the long side, but only taking the first angle that forms the acute angle with the long side.

In addition, embodiments of the present disclosure further provide a mask. The mask mainly includes: a mask frame; and a plurality of sub masks fixed to the mask frame. In one embodiment, the sub masks are stretched using anyone of the above method for stretching a sub mask.

Optionally, the sub mask according to one embodiment is formed of metal in view of the fact that the fine mask plate required for vapor deposition is mostly made of a metal having good ductility.

An embodiment of the present disclosure provides a substrate, which is formed using the mask according to any one of the above embodiments.

Further, a panel is further provided, and the panel is formed using the above mask. Optionally, the panel is an OLED display panel.

An embodiment of the present disclosure provides a display device, which includes the above substrate.

The above mask is stretched using an approach involving the first angle, and thus a component force is applied along the extending direction of the short side of the sub mask. Accordingly, the wrinkles of the sub mask may be reduced, thereby improving flatness of the sub mask, which in turn may ensure the quality of the vapor deposition of the films and layers of the panel formed using the mask.

Embodiments of the present disclosure may have the following advantages.

With the present embodiments, the stretcher holds the holding regions positioned at four corners of the sub mask to be stretched, and stretches the sub mask with a first tension along a direction having a first angle with respect to an extending direction of a long side of the sub mask in a plane where the sub mask is located. Accordingly, a component force is applied along the extending direction of the short side of the sub mask, and thus the sub mask is stretched along the extending direction of the short side thereof in addition to being stretched along the extending direction of the long side thereof. Accordingly, the wrinkles of the sub mask may be reduced, thereby improving flatness of the sub mask, and it is easily achievable.

Although some embodiments of the present embodiments have been described, those skilled in the art can make other changes and modifications to these embodiments once they have acquired the basic inventive concept. Therefore, the appended claims are intended to be interpreted as including all these embodiments as well as all the changes and modifications that fall within the scope of the present embodiment. Obviously, those skilled in the art can make various modifications and variations to the embodiments without departing from the spirit and scope of the embodiments. In this way, if these modifications and variations of the present embodiment fall within the scope of the claims of the present embodiment and the equivalent technologies thereof, the present embodiment is also intended to include these changes and modifications.

1. A method for stretching a sub mask, comprising:
holding holding regions positioned at four corners of the sub mask to be stretched;
stretching the sub mask with a first tension along a direction having a first angle with respect to an extending direction of a long side of the sub mask in a plane where the sub mask is located; and
fixing the sub mask when a flatness of the sub mask reaches a first reference value,
wherein the first angle is greater than 0 degree and smaller than 90 degrees.

2. The method according to claim 1, wherein the first tension is substantially symmetrical with respect to a center of the sub mask.

3. The method according to claim 1, wherein at least two tensions among the first tension are substantially symmetrical respect to an axis passing through a center of the sub mask.

4. The method according to claim 1, wherein a component force of the first tension in an extending direction of a short side of the sub mask reduces as a size ratio of the sub mask decreases,
wherein the size ratio of the sub mask is a ratio between the short side and the long side of the sub mask.

5. The method according to claim 1, wherein a component force of the first tension in an extending direction of a short side of the sub mask is substantially constant during the stretching.

6. The method according to claim 5, wherein the step of stretching the sub mask with a first tension along a direction having a first angle with respect to an extending direction of a long side of the sub mask in a plane where the sub mask is located further comprises:
stretching the sub mask with a varying first tension along a direction having a varying first angle with respect to the extending direction of the long side of the sub mask; or
stretching the sub mask with a fixed first tension along a direction having a fixed first angle with respect to the extending direction of the long side of the sub mask.

7. The method according to claim 1, wherein a component force of the first tension in an extending direction of a short side of the sub mask is gradually reduced during the stretching.

8. The method according to claim 7, wherein the step of stretching the sub mask with a first tension along a direction having a first angle with respect to an extending direction of a long side of the sub mask in a plane where the sub mask is located further comprises:
stretching the sub mask with a fixed first tension along a direction having a gradually reduced first angle with respect to the extending direction of the long side of the sub mask; or
stretching the sub mask with a gradually reduced first tension along a direction having a fixed first angle with respect to the extending direction of the long side of the sub mask.

9. (canceled)

10. A mask, comprising:
a mask frame; and
a plurality of sub masks fixed to the mask frame,
wherein the sub masks are stretched using the method for stretching a sub mask according to claim 1.

11. The mask according to claim 10, wherein the sub mask is formed of metal.

12. A substrate, formed using the mask according to claim 10.

13. A display device, comprising the substrate according to claim 12.

14. A stretcher, comprising:
a holder, configured to hold holding regions positioned at four corners of a sub mask to be stretched; and
a rotation shaft, connected to the holder, wherein the rotation shaft is configured to change a direction to stretch the sub mask with a first tension along a direction having a first angle with respect to an extending direction of a long side of the sub mask in a plane where the sub mask is located.
